(19) United States
(12) Patent Application Publication
(10) Pub. No.: US 2026/0302727 A1
(43) Pub. Date: Oct. 1, 2026

(54) LASER DEVICE

(71) Applicant: NICHIA CORPORATION, Anan-shi (JP)

(72) Inventors: Yutaka YOSHIKAWA, Yokohama-shi (JP); Hidenori MATSUO, Hadano-shi (JP)

(73) Assignee: NICHIA CORPORATION, Anan-shi (JP)

(21) Appl. No.: 19/577,916

(22) Filed: Mar. 25, 2026

(30) Foreign Application Priority Data
Mar. 28, 2025 (JP) 2025-056988

(51) Int. Cl. H01S 5/0687; H01S 5/024; H01S 5/0625; H01S 5/50

(52) U.S. Cl. CPC H01S 5/0687; H01S 5/02415; H01S 5/06256; H01S 5/06258; H01S 5/50

(57) ABSTRACT

A laser device includes: a light source unit of a self-injection locked type, the light source unit including a semiconductor laser element and an optical resonator; a frequency monitor configured to monitor a frequency of laser light extracted from the light source unit by using an interferometer; and a control circuit configured to control at least one of an oscillation frequency of light emitted from the semiconductor laser element and a resonant frequency of the optical resonator based on an output of the frequency monitor. A free spectral range of the interferometer is different from a free spectral range of the optical resonator. An interference signal from the frequency monitor is different at each of the resonant frequencies of the optical resonator adjacent to each other.

### CROSS-REFERENCE TO RELATED APPLICATION

This application claims priority to Japanese Patent Application No. 2025-056988, filed on Mar. 28, 2025, the disclosure of which is hereby incorporated by reference in its entirety.

### TECHNICAL FIELD

The present disclosure relates to a laser device.

### BACKGROUND

Japanese Patent Publication No. 2017-147299 A discloses a semiconductor laser light source including a light source block in which a semiconductor laser configured to oscillate in a single mode is mounted, and a wavelength locker block in which an etalon filter is mounted. The semiconductor laser light source is configured in such a manner that part of reflected light from the etalon filter in the wavelength locker returns to a semiconductor laser chip.

### SUMMARY

As a technique for achieving a narrow linewidth of a laser, a self-injection locked (SIL) type laser light source has been known (for example, see Japanese Patent Publication No. 2017-147299 A). In the known technique, an output current of a wavelength monitoring photodiode that receives transmitted light of an optical resonator is standardized at an output current of an intensity monitoring photodiode. An oscillation frequency of a semiconductor laser is controlled so that a signal obtained by the standardization has a predetermined value. In this case, there are standing waves corresponding to different resonant frequencies in the optical resonator. Such a wave is called a longitudinal mode. However, in the known technique, the same signal is obtained even when the resonant frequencies are different. This makes it difficult to determine which longitudinal mode the light emitted from a semiconductor laser element is locked to. Accordingly, there might be a case in which self-injection locking cannot be performed at a specific resonant frequency in the optical resonator; for example, the longitudinal mode of emitted light is locked to a longitudinal mode adjacent to the target longitudinal mode.

The present disclosure has been made in view of the above disadvantages, and an object thereof is to provide a laser device that allows self-injection locking to be performed at a specific resonant frequency in an optical resonator.

A laser device according to an aspect of the present disclosure includes: a light source unit of a self-injection locked type, the light source unit including a semiconductor laser element and an optical resonator; a frequency monitor configured to monitor a frequency of laser light extracted from the light source unit by using an interferometer; and a control circuit configured to control at least one of an oscillation frequency of light emitted from the semiconductor laser element and a resonant frequency of the optical resonator based on an output of the frequency monitor, in which a free spectral range of the interferometer is different from a free spectral range of the optical resonator, and an interference signal from the frequency monitor is different at each of the resonant frequencies of the optical resonator adjacent to each other.

With the laser device according to the present disclosure, self-injection locking can be performed at a specific resonant frequency of the optical resonator.

### BRIEF DESCRIPTION OF DRAWINGS

FIG. 1 is a diagram for explaining the principle of a self-injection locked type light source.

FIG. 2 is a diagram illustrating an image of a standing wave in an optical resonator.

FIG. 3 is a diagram for explaining the principle of monitoring a frequency of laser light.

FIG. 4A is a diagram for explaining interference by a wedge.

FIG. 4B is a diagram illustrating an example of an intensity distribution of an interference fringe.

FIG. 4C is a diagram illustrating an example of an intensity distribution of an interference fringe.

FIG. 5A is a diagram illustrating a configuration of a laser device 100 according to a first embodiment.

FIG. 5B is a diagram illustrating arrangement of the laser device 100 according to the first embodiment.

FIG. 6 is a diagram illustrating an example of a control flow performed by a control circuit 150.

FIG. 7 is a diagram depicting an example of output of a frequency monitor 130.

FIG. 8 is a diagram illustrating a state of analysis results fitting.

FIG. 9 is a diagram illustrating a configuration of the laser device 100 according to a first modified example of the first embodiment.

FIG. 10 is a diagram illustrating a configuration of the laser device 100 according to a second modified example of the first embodiment.

FIG. 11A is a diagram illustrating a configuration of a laser device 100 according to a second embodiment.

FIG. 11B is a diagram illustrating arrangement of the laser device 100 according to the second embodiment.

FIG. 12 is a diagram illustrating a configuration of the laser device 100 according to a modified example of the second embodiment.

FIG. 13 is a diagram illustrating a configuration of a laser device 100 according to a third embodiment.

FIG. 14 is a diagram illustrating a configuration of a laser device 100 according to a fourth embodiment.

FIG. 15 is a diagram illustrating a configuration of the laser device 100 according to a modified example of the fourth embodiment.

FIG. 16 is a diagram illustrating a configuration of a laser device 100 according to a fifth embodiment.

FIG. 17 is a diagram illustrating occurrence rates of oscillation frequencies of laser devices according to Example 1 and Comparative Example 1.

### DETAILED DESCRIPTION

Embodiments of the present disclosure will be described below with reference to the drawings. In the drawings, the same reference characters are used to designate the same or similar constituent elements. In the following embodiments, redundant descriptions and reference characters may be omitted. The drawings used in the following description are all schematic, and the dimensional relationship between elements, the ratio of elements, and the like illustrated in the drawings do not necessarily match the actual ones. The dimensional relationship between elements, the ratio of elements, and the like are not necessarily consistent throughout the drawings.

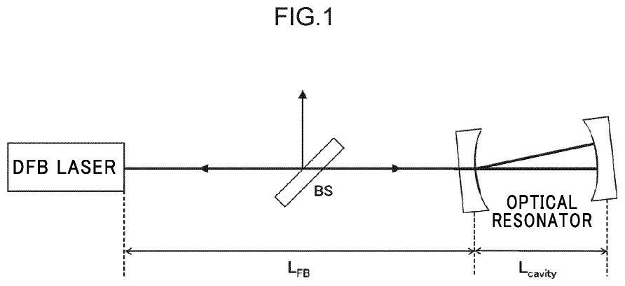

Prior to describing a laser device 100 according to the present disclosure, a self-injection locked type light source will be briefly described. FIG. 1 is a diagram for explaining the principle of the self-injection locked type light source. In FIG. 1, a light source having a SIL distributed feedback (SIL-DFB) structure is illustrated as an example of the self-injection locked type light source.

The SIL-DFB structure is formed of a collimated DFB laser and an optical resonator (also referred to as “cavity”). When light emitted from the DFB laser resonates with the optical resonator (that is, an oscillation frequency of the DFB laser is approximately equal to a resonant frequency of the optical resonator), light reflected from the inside of the optical resonator returns to the DFB laser. At this time, optical feedback effect is exerted to narrow a spectral linewidth. In this case, the DFB laser and the optical resonator operate in their entirety as a single laser light source. In this state, a beam splitter disposed in an optical path between the DFB laser and the optical resonator is used to extract part of the laser light, so that the laser light with a narrowed spectral linewidth can be output.

For the light source having the SIL-DFB structure to stably oscillate, a feedback path length L_{FB} and a resonator length L_{cavity} need to satisfy a specific relational expression with the wavelength of light. The feedback path length L_{FB} needs to be equal to a length obtained by adding a constant term to an integer multiple of a half-wavelength of light. Conditions of the resonator length L_{cavity} vary depending on the configuration of the resonator. When the resonator is a general Fabry-Perot resonator, the feedback path length L_{FB} and the resonator length L_{cavity} may be an integer multiple of a half-wavelength of light. When the optical resonator is a confocal-arrangement Fabry-Perot resonator (that is, a confocal resonator), the feedback path length L_{FB} and the resonator length L_{cavity} may be an integer multiple of a quarter-wavelength of light. The confocal resonator is an optical resonator in which a mirror curvature radius and a distance from one mirror to the other mirror are set to be equal to each other. The confocal resonator can ensure a resonant state in which the light passes through a V-shaped optical path, by slightly tilting the resonator as illustrated in FIG. 1. This V-shaped path can spatially separate the light resonating with the resonator and the light not resonating with the resonator from each other, and can return the light to the DFB laser only when the DFB laser light resonates with the resonator. FIG. 1 illustrates an example of a case with the confocal resonator. The feedback path length L_{FB} indicates a length from the DFB laser to a mirror, disposed closer to the DFB laser, of a pair of mirrors. The resonator length L_{cavity} indicates the length between the pair of mirrors.

When the above resonant conditions are satisfied, in the resonator, the phase of a light wave immediately after the incidence coincides with the phase of a light wave that has returned after making one-round trip in the resonator. Due to this, all the light waves that repeat round trips are superimposed and reinforce each other, and consequently a standing wave is generated in the optical resonator. In the case in which the round trip distance in the resonator is an integer multiple of a half-wavelength of light, the above-described condition for the light waves to reinforce each other is satisfied, and thus there can be a plurality of standing waves corresponding to different resonant frequencies in the optical resonator. Such a wave is called a longitudinal mode.

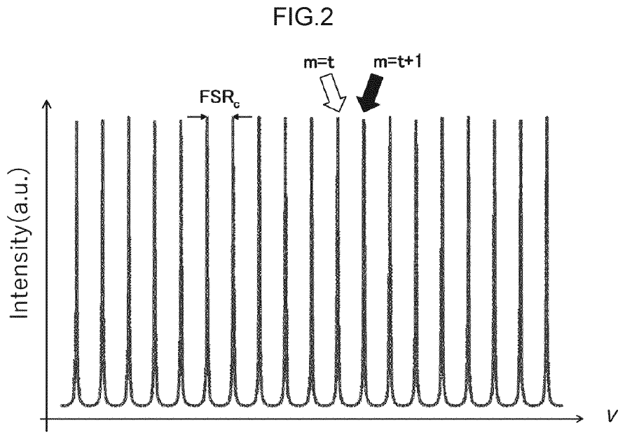

FIG. 2 is a diagram illustrating an image of a standing wave in an optical resonator alone. In FIG. 2, the horizontal axis represents a frequency v of light, and the vertical axis represents intensity of light. The standing wave in the optical resonator has a discrete distribution form as illustrated in FIG. 2. In this case, it is assumed that a white arrow indicates a target longitudinal mode (here, m=t) which is desired for the emitted light to be locked. However, as described above, in the known technique, the wavelength locker does not read the signal intensity at the absolute frequency, but reads the standardized signal intensity of the photodiode. The standardized signal intensity of the photodiode of the known technique vibrates, and when the resonant frequency deviates by one free spectral range (FSR), the same signal is obtained even when the resonant frequencies are different. Therefore, the known technique cannot determine which longitudinal mode the light emitted from the DFB laser is locked to. Accordingly, even when the oscillation frequency of the DFB laser is controlled, the emitted light may be locked to, for example, a longitudinal mode (here, m=t+1) adjacent to the target longitudinal mode as indicated by a black arrow.

In this case, FSR_{c}, which is a free spectral range of the optical resonator, is approximately several GHz. Accordingly, in the known technique, the frequency of the light extracted from the light source deviates from the target frequency by approximately several GHz. Then, the laser device 100 according to the present disclosure monitors the frequency of laser light extracted from a self-injection locked type light source unit by using an interferometer. Thus, the frequency of the laser light is controlled based on the result of monitoring the frequency.

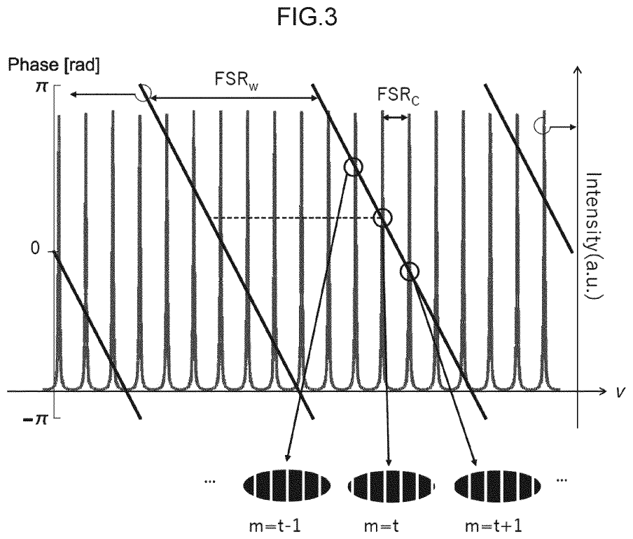

Next, the principle of monitoring the frequency of laser light by the laser device 100 according to the present disclosure will be described in detail. FIG. 3 is a diagram for explaining the principle of monitoring the frequency of laser light. In FIG. 3, the horizontal axis represents a frequency v of light, the vertical axis on the left side represents the phase of light, and the vertical axis on the right side represents intensity of light of a standing wave in an optical resonator alone.

In the drawing, a case of using a wedge as an interferometer is illustrated as an example. Interference by the wedge will be described below. A free spectral range FSR_{w} of the wedge is different from the free spectral range FSR_{c} of the optical resonator.

Due to this, as is clear from the fact that the positions of three circles on the vertical axis are different in the drawing, the phases of interference fringes (also referred to as “fringes”) are different between a longitudinal mode “m=t−1”, a longitudinal mode “m=t”, and a longitudinal mode “m=t+1”. That is, an interference signal from the frequency monitor is different at each of the adjacent resonant frequencies of the optical resonator. Therefore, by storing information on the interference fringes as a reference in advance, the laser device 100 can monitor the frequencies of the laser light based on the difference between the reference and the interference signal from the frequency monitor.

It is also possible to distinguish between an interference signal caused by the wedge in the longitudinal mode “m=t” of the optical resonator and an interference signal by the wedge in the longitudinal mode of the optical resonator separated by one FSR_{w} of the wedge. As illustrated in FIG. 3, FSR_{W} of the wedge can be selected in such a manner that the phase of the interference fringe caused by the wedge and the phase at the resonant frequency of the optical resonator do not become the same as that in the case of “m=t” when separated by one FSR_{w}. That is, the resonant frequency of the optical resonator with the wedge at “m=t”, and the resonant frequency of the optical resonator at an intersection between a broken line laterally extending and the wedge do not overlap each other. Accordingly, the laser device 100 can determine the locked longitudinal mode.

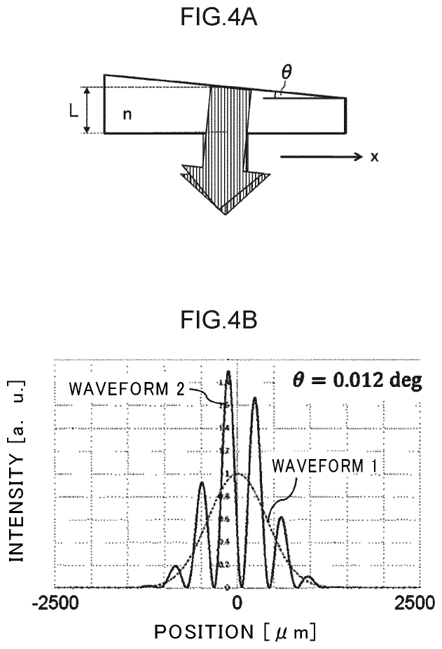

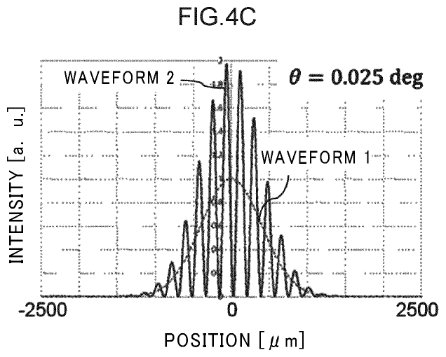

FIG. 4A is a diagram for explaining interference caused by a wedge. As illustrated in FIG. 4A, the wedge is an optical element whose thickness gradually changes from one end toward the other end (in the x direction in FIG. 4A). This makes it possible to generate an interference fringe by the interference between light reflected on a front surface of the wedge and light reflected on a back surface of the wedge.

Each of FIGS. 4B and 4C is a diagram illustrating an example of an intensity distribution of the interference fringe. FIGS. 4B and 4C depict waveforms of light when wedge angles θ are different. In FIGS. 4B and 4C, the horizontal axis represents a position in the x direction, and the vertical axis represents intensity of light. A waveform 1 indicates a waveform of incident light on the wedge, and a waveform 2 indicates a waveform of interference light at the wedge. FIG. 4B depicts an example in which the wedge angle θ is 0.012°. FIG. 4C depicts an example in which the wedge angle θ is 0.025°. As depicted in FIGS. 4B and 4C, when the wedge angles θ are different, the generated interference fringes are different accordingly. As described above, it is known that the intensity distribution of the interference fringe at the position x depends on the wedge angle θ.

Because the interference itself by the wedge may be known as an existing technique, further description thereof is omitted herein. The laser device 100 according to the present disclosure monitors a frequency of laser light extracted from a self-injection locked type light source unit by using an interferometer such as a wedge. Then, the frequency of the laser light is controlled based on the result of the monitored frequency. The configuration of the laser device 100 that implements these functions will be described in detail in a plurality of embodiments.

### First Embodiment

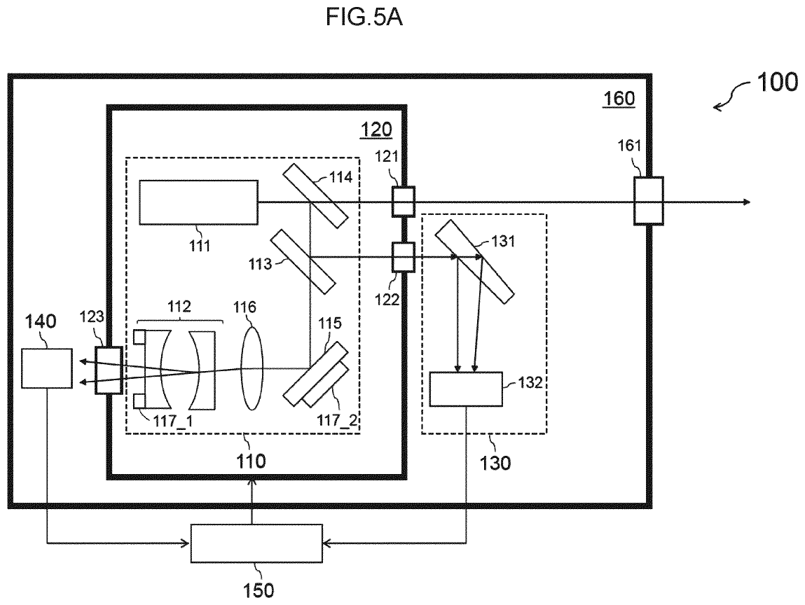

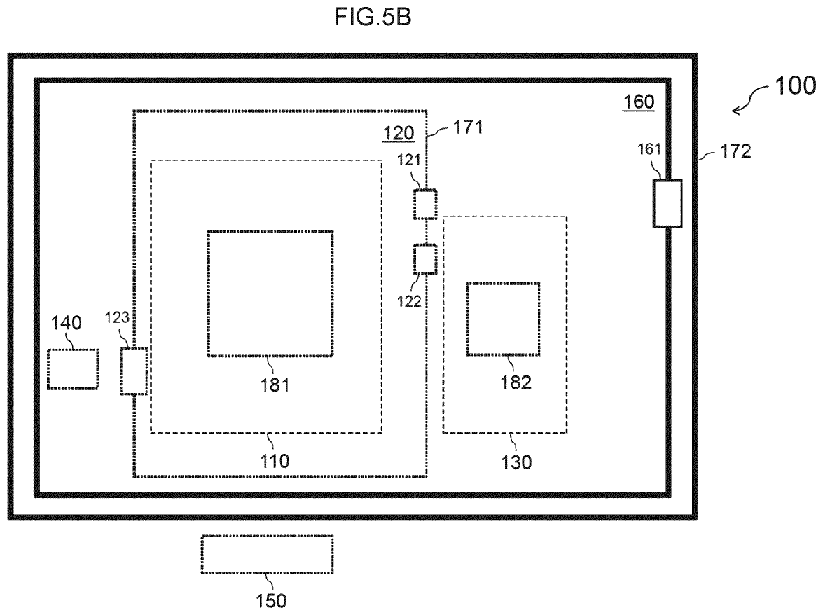

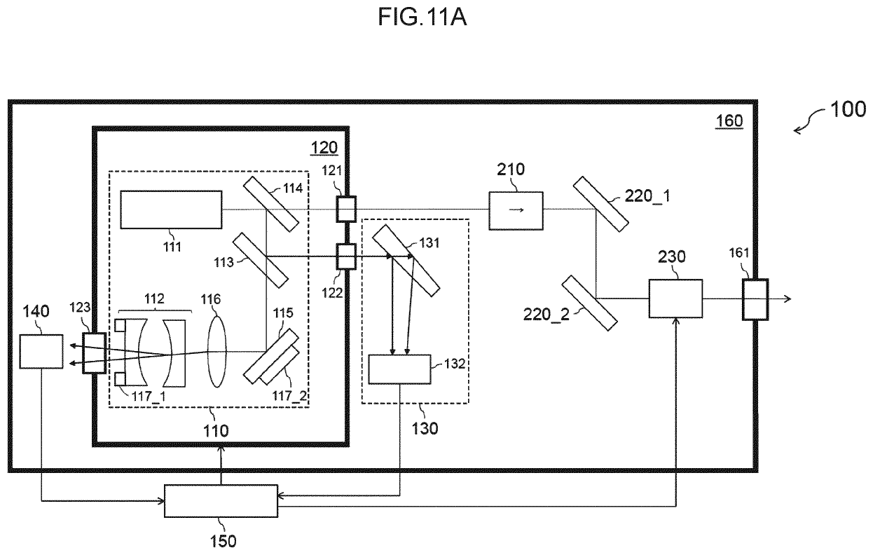

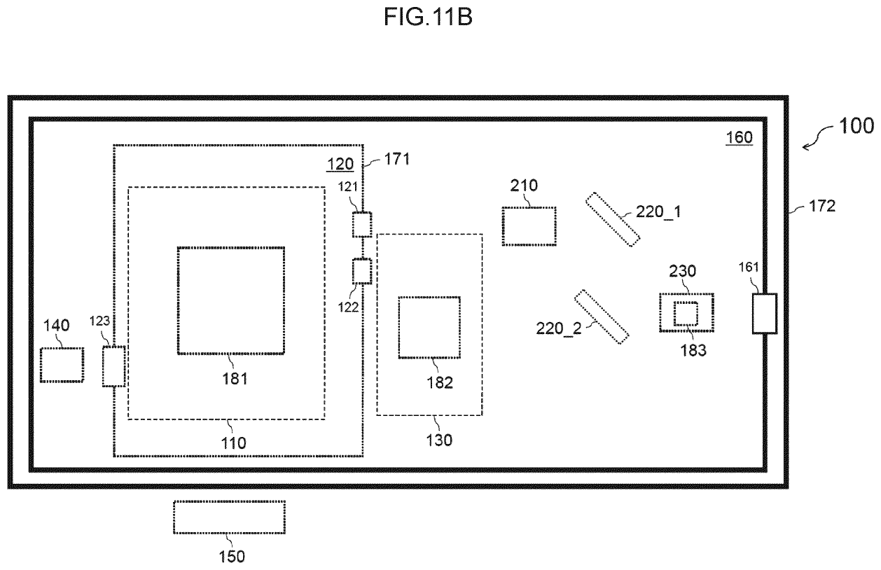

FIG. 5A is a diagram illustrating a configuration of a laser device 100 according to a first embodiment. FIG. 5B is a diagram illustrating arrangement of the laser device 100 according to the first embodiment. The laser device 100 includes a light source unit 110, a first cover 120, a frequency monitor 130, a photodiode 140, a control circuit 150, and a second cover 160. For convenience of description, in FIG. 5B, internal configurations of the light source unit 110 and the frequency monitor 130, optical paths, and control lines are not illustrated and simplified with only broken lines. Further, FIG. 5B illustrates a top view of the laser device 100, where a first Peltier element 181 and a second Peltier element 182, which are not visible when viewed from above, are indicated by dotted lines. The same applies to FIG. 11B to be described below.

The light source unit 110 is a unit serving as a self-injection locked type light source. The light source unit 110 includes a semiconductor laser element 111 and an optical resonator 112. In the present embodiment, the light source unit 110 may further include a first beam splitter 113, a second beam splitter 114, a mirror 115, and a lens 116. These elements may be arranged in the order of the second beam splitter 114, the first beam splitter 113, the mirror 115, and the lens 116 when viewed from the semiconductor laser element 111 side in an optical path between the semiconductor laser element 111 and the optical resonator 112.

The semiconductor laser element 111 is an element that performs laser oscillation using a semiconductor material. Although the DFB laser is described as an example in FIG. 1, the semiconductor laser element is not limited thereto. As the semiconductor laser element 111, for example, a DFB laser element, a distributed Bragg reflector (DBR) laser element, a photonic crystal surface emitting laser (PCSEL) element, or a master oscillator power amplifier (MOPA) element may be used. The MOPA is an element in which a semiconductor laser and a semiconductor optical amplifier (SOA) are integrated. Examples of the semiconductor material include III-V group semiconductors such as gallium nitride (GaN)-based semiconductors, gallium arsenide (GaAs)-based semiconductors, and indium phosphide (InP)-based semiconductors. A peak wavelength of the light emitted from the semiconductor laser element 111 may be, for example, in a range of 340 nm to 2000 nm, in a range of 360 nm to 700 nm, or in a range of 360 nm to 580 nm.

The semiconductor laser element 111 may be housed in a package and hermetically sealed. This makes it possible to suppress deterioration of the semiconductor laser element due to optical dust collection. As the peak wavelength of the emitted light is shorter, the emitted light is more influenced by optical dust collection; however, the influence of optical dust collection can be reduced by hermetically sealing the package. The package may be, for example, a CAN package in which a lead terminal extends to a bottom surface or lateral surface of the package, or may be a surface-mount device package in which a lead terminal does not extend. In addition to the semiconductor laser element 111, a desired optical element such as a collimator lens that collimates laser light or a mirror that adjusts the optical path of laser light may be disposed inside the package.

The optical resonator 112 has a structure in which a pair of mirrors is disposed to face each other, and generates a standing wave of light by confining light having a specific wavelength between the pair of mirrors. As the optical resonator 112, for example, a Fabry-Perot resonator or an etalon may be used. A first piezoelectric element 117_1 may be attached to the optical resonator 112. The first piezoelectric element 117_1 is attached to the subsequent-stage mirror of the pair of mirrors constituting the optical resonator 112. Compared to a case in which the first piezoelectric element 117_1 is attached to the previous-stage mirror of the pair of mirrors constituting the optical resonator 112, the control circuit 150 can change only the resonator length L_{cavity} by controlling the voltage of the first piezoelectric element 117_1. This can facilitate the control of the resonant frequency of the optical resonator 112.

When the light emitted from the semiconductor laser element 111 resonates with the optical resonator 112, the light reflected back from the inside of the optical resonator 112 returns to the semiconductor laser element 111, and the spectral linewidth of the emitted light is narrowed. In this case, the semiconductor laser element 111 and the optical resonator 112 in their entirety operate as one laser light source. The narrowed spectral linewidth of the laser light may be, for example, in a range of 500 Hz to 1 MHz.

The first beam splitter 113 and the second beam splitter 114 split the incident light into two light beams. The second beam splitter 114 splits the light emitted from the semiconductor laser element 111 into output light to be output from the light source unit 110 and reference light to be introduced into the optical resonator 112. The reference light is light for optical feedback. The first beam splitter 113 transmits part of the reference light split by the second beam splitter 114, and reflects part of the reference light to thereby extract part of the laser light from the light source unit 110.

The mirror 115 reflects the reference light transmitted through the first beam splitter 113 toward the optical resonator 112. A second piezoelectric element 117_2 may be attached to the mirror 115. The control circuit 150 can change the feedback path length L_{FB} by controlling the voltage of the second piezoelectric element 117_2. The first piezoelectric element 117_1 and the second piezoelectric element 117_2 are collectively referred to as “piezoelectric elements 117”.

The lens 116 focuses, toward the optical resonator 112, the reference light reflected by the mirror 115, and spatially couples the reference light to the optical resonator 112. Here, when the emitted light resonates with the optical resonator 112, resonant light is reflected back from the inside of the optical resonator 112. In this case, the resonant light passes through the lens 116, is reflected by the mirror 115, passes through the first beam splitter 113, is reflected by the second beam splitter 114, and returns to the semiconductor laser element 111.

The light source unit 110 is not limited to the above-described configuration. The light source unit 110 may be modified as appropriate by adding another configuration or omitting part of the configuration. The laser device 100 may further include a first stage 171, on which the above-described light source unit 110 is mounted. The first cover 120 is a protective member that covers the first stage 171.

A space surrounded by the first stage 171 and the first cover 120 may be hermetically sealed with argon (Ar) gas, nitride (N2) gas, or the like. This can allow the temperature, humidity, and the like of the light source unit 110 to be protected from the external environment, and thus can stabilize the frequency of the laser light. Examples of the material of the first cover 120 include super invar, aluminum, and copper.

The first cover 120 may be provided with a first window 121, a second window 122, and a third window 123. The first window 121 is a window for outputting the output light split by the second beam splitter 114 to the outside of the first cover 120. The second window 122 is a window for outputting the laser light split by the first beam splitter 113 to the outside of the first cover 120. The third window 123 is a window for outputting the transmitted light having passed through the optical resonator 112 to the outside of first cover 120. Examples of the material of the first window 121, the second window 122, and the third window 123 include silica, BK7, and calcium fluoride, or the like.

The laser device 100 may further include a second stage 172, on which the first stage 171 is mounted, and the first Peltier element 181 disposed between the first stage 171 and the second stage 172.

The frequency monitor 130 monitors the frequency of the laser light extracted from the light source unit 110, that is, the laser light split by the first beam splitter 113 in this case, using an interferometer. The frequency monitor 130 may include a wedge 131 as an example of the interferometer and a light-receiving element 132. As described above, a free spectral range of the interferometer, that is, the free spectral range FSR_{w} of the wedge 131 in this case is different from the free spectral range FSR_{c} of the optical resonator 112. Further, an interference signal from the frequency monitor 130 is different at each of the adjacent resonant frequencies of the optical resonator 112.

The wedge 131 is an optical element whose thickness gradually changes from one end to the other end. This makes it possible to generate an interference fringe by the interference between the light reflected on the front surface of the wedge 131 and the light reflected on the back surface thereof. Although a case in which the wedge 131 is used as an interferometer is described as an example, the interferometer may employ any element, such as etalon, that can generate interference fringes by causing light to interfere with each other.

The light-receiving element 132 receives the light reflected by both surfaces of the wedge 131. As the light-receiving element 132, for example, a camera, a linear sensor, or a split photodiode (position sensitive detector (PSD)) may be used. The light-receiving element 132 detects an interference signal related to the interference fringe. Such a signal is provided as an output of the frequency monitor 130 to the control circuit 150.

The photodiode 140 receives the transmitted light having passed through the optical resonator 112. The output current of the photodiode 140 is converted into a voltage. The value of the converted voltage is useful for determining whether the emitted light resonates with the optical resonator 112. Accordingly, the voltage converted from the output current of the photodiode 140 may also be supplied to the control circuit 150.

The control circuit 150 controls at least one of the oscillation frequency of the light emitted from the semiconductor laser element 111 and the resonant frequency of the optical resonator 112 based on the output of the frequency monitor 130. As the control circuit 150, for example, a microcontroller, a field programmable gate array (FPGA), a single board computer (SBC), or a computer may be used.

The frequency monitor 130 and the photodiode 140 may be mounted on the second stage 172 as well as the first stage 171. The second Peltier element 182 configured to adjust the temperature of the frequency monitor 130 may be mounted near the frequency monitor 130 on the second stage 172. The second Peltier element 182 may be disposed, for example, between the frequency monitor 130 and the second stage 172.

The control circuit 150 may be disposed outside the first stage 171 and the second stage 172. The control circuit 150 controls a current supplied to the first Peltier element 181, thereby reducing a temperature change in the light source unit 110. With this, in the light source unit 110, the oscillation frequency can be stabilized by reducing a temporal change in the feedback path length L_{FB} and the resonator length L_{cavity} due to the temperature change. The control circuit 150 controls a current supplied to the second Peltier element 182, whereby a temperature-dependent change in length of the frequency monitor, particularly, the wedge 131 is reduced. This can reduce a deviation of the optical path length due to the expansion and contraction of the wedge 131, and can reduce an error of the interference signal caused by the frequency monitor 130. The control circuit 150 may be disposed on the first stage 171 or the second stage 172.

As described above, the laser device 100 includes the first stage 171, on which the light source unit 110 is mounted, and the second stage on which the frequency monitor 130 and the first stage 171 are mounted. The first Peltier element 181 is disposed between the first stage 171 and the second stage 172, and the second Peltier element 182 is disposed near the frequency monitor 130. In this manner, the light source unit 110 and the frequency monitor 130 are supported by the different stages, and the temperatures thereof are controlled by the different Peltier elements. This can allow the temperature of the light source unit 110 and the temperature of the frequency monitor 130 to be individually controlled, and thus can reduce the influence of a change in one of the temperatures on the other. Therefore, it is possible to improve the controllability for the oscillation frequency or reduce the error of the interference signal.

The second cover 160 is a protective member that covers the second stage 172. This can allow the entire laser device 100 to be protected from the external environment. The material of the second cover 160 may be the same as or similar to the material of the first cover 120.

The second cover 160 may be provided with an output window 161. The output window 161 is a window for outputting the light output from the first window 121 to the outside of the second cover 160, that is, the outside of the laser device 100. The material of the output window 161 may be the same as or similar to the material of the first window 121, the second window 122, and the third window.

As illustrated in FIG. 5B, an end of the first stage 171 may overlap with an end of the first cover 120 in a top view. In this case, when the first stage 171 is a plate-shaped stage, the first cover 120 may include a wall and a top plate.

In contrast, when the first stage 171 is a recess-shaped stage, the first cover 120 may include only a top plate. In this case, each element constituting the light source unit 110 may be disposed in a recessed portion of the first stage 171. The first window 121, the second window 122, and the third window 123 may be provided on the sidewalls of the recessed portion of the first stage 171, instead of the first cover 120.

On the other hand, in a top view, an end of the second stage 172 may be located at the outer periphery relative to an end of the second cover 160. That is, the second stage 172 may have a larger area than the second cover 160.

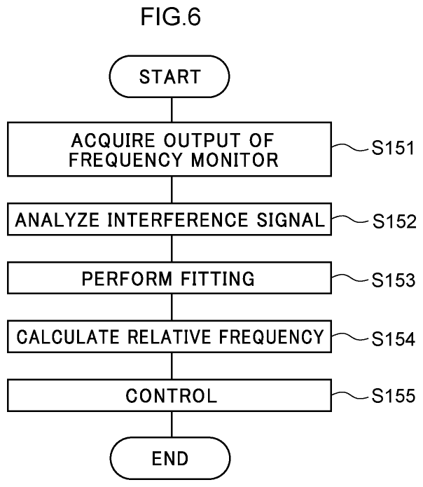

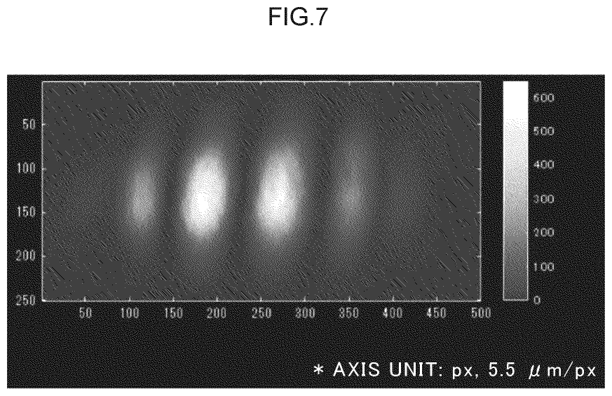

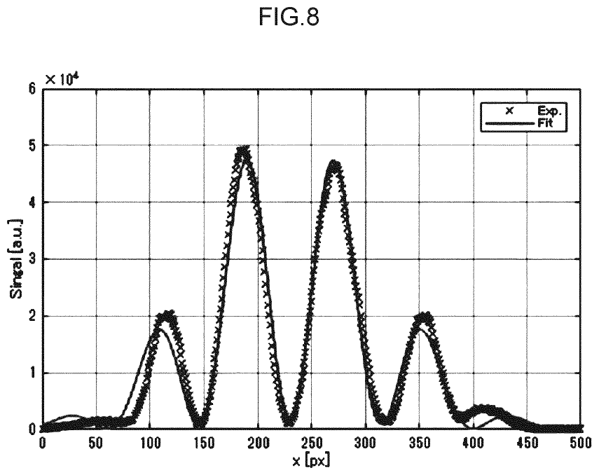

In the first embodiment, the laser device 100 is not limited to the above-described configuration. The laser device 100 may be modified as appropriate by adding another configuration or omitting part of the configuration. Next, operations of the control circuit 150 will be described in detail using a control flow in FIG. 6 while referring to FIGS. 7 and 8.

FIG. 6 is a diagram illustrating an example of a control flow performed by the control circuit 150. The control circuit 150 may start the control flow in response to determining that the emitted light has resonated with the optical resonator 112. Whether the emitted light has resonated with the optical resonator 112 can be determined by converting the output current from the photodiode 140 into a voltage.

In step S151, the control circuit 150 acquires an output of the frequency monitor 130. FIG. 7 is a diagram illustrating an example of an output of the frequency monitor 130. FIG. 7 depicts an image obtained by capturing an interference fringe generated by the wedge 131 with a camera serving as the light-receiving element 132. The control circuit 150 may, for example, acquire such an image as an interference signal from the frequency monitor 130.

In step S152, the control circuit 150 analyzes the interference signal. The control circuit 150 may integrate the images depicted in FIG. 7 in a fringe direction (here, the vertical direction in the drawing), for example. FIG. 8 is a diagram illustrating a state of analysis results fitting. In the drawing, x marks indicate analysis results, that is, a waveform obtained by plotting the values obtained by integrating the images in the fringe direction. In the above description, a case in which the control circuit 150 obtains such a waveform by acquiring the images from the frequency monitor 130 and analyzing the images is described as an example, but there is no limitation to this example. The control circuit 150 can also directly obtain such a waveform by acquiring signals detected by a line detector from the frequency monitor 130.

In step S153, the control circuit 150 performs fitting on the analysis results using a predetermined fitting function. Here, in a case of fitting the intensity distribution of the interference fringe of the wedge, when A is a parameter associated with the amplitude of a beam, xc is a center position of the beam, x is a coordinate in a direction in which the beam spreads, W is a parameter associated with the spread of the beam, Vis a parameter associated with the contrast of the interference fringe, K is a parameter associated with the wave number of the interference fringe, Φ is a phase, and d is an offset, a function expressed by the following equation can be used as a fitting function.

$$f ( x ) = A exp ( - \frac{2 {( x - {x}_{c} )}^{2}}{{W}^{2}} ) ( 1 + \frac{2 V}{1 + {V}^{2}} cos ( K ( x - {x}_{c} ) - ϕ ) ) + d \qquad [ Equation 1 ]$$

In the first term of Equation 1, the product of A and an exponential function represents a Gaussian beam envelope, and the other portions represent the interference fringe. A solid line in FIG. 8 indicates a waveform obtained by fitting the analysis results by the method of least squares using the above-mentioned function.

In step S154, the control circuit 150 calculates a relative frequency. At this time, the control circuit 150 can calculate a relative frequency indicating a difference from a specific resonant frequency on the basis of the phase Φ in Equation 1.

In step S155, the control circuit 150 controls at least one of the oscillation frequency of the light emitted from the semiconductor laser element 111 and the resonant frequency of the optical resonator 112 based on the output of the frequency monitor 130. At this time, the control circuit 150 may control a current supplied to the semiconductor laser element 111 based on the relative frequency. In addition, the control circuit 150 may control a current supplied to the first Peltier element 181 based on the relative frequency. The control circuit 150 may control a voltage of the second piezoelectric element 117_2 attached to the mirror 115 based on the relative frequency. The control circuit 150 may control a voltage of the first piezoelectric element 117_1 attached to the optical resonator 112 based on the relative frequency. The control may be, for example, a correction control to be performed only once, or a continuous-time control such as a proportional integral differential (PID) control.

This makes it possible to cause the emitted light to oscillate and be locked at a targeted specific resonant frequency of the optical resonator 112. With the laser device 100 according to the present embodiment, self-injection locking can be performed at a specific resonant frequency of the optical resonator 112.

### First Modified Example of First Embodiment

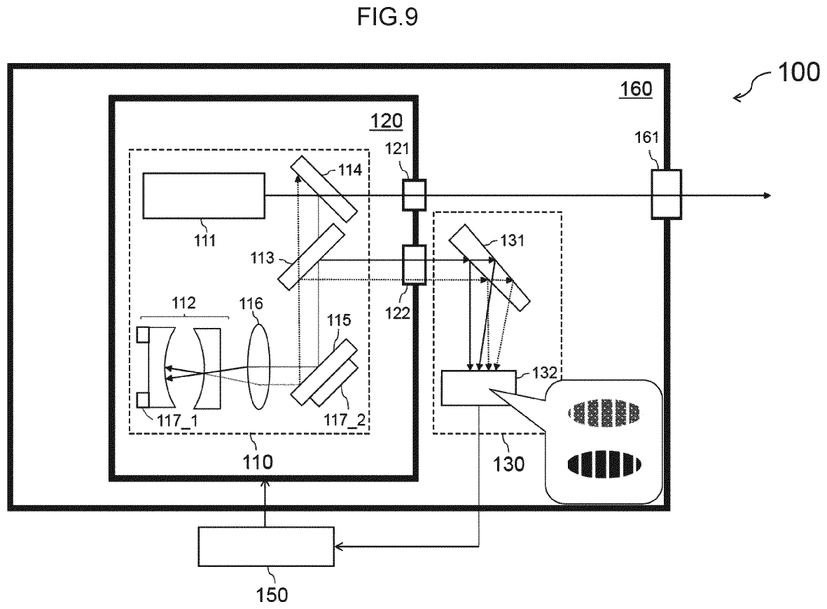

FIG. 9 is a diagram illustrating a configuration of the laser device 100 according to a first modified example of the first embodiment. In FIG. 9, the same reference signs are given to the same or similar constituent elements as or to those in FIGS. 5A and 5B, and redundant description thereof will be omitted except for the following differences. The same applies to other embodiments and other modified examples described below as well.

The present modified example differs from the first embodiment in the following points.
The orientation of the first beam splitter 113 is rotated by 90 degrees.
The first cover 120 is not provided with the third window 123.
The laser device 100 does not include the photodiode 140.

In the present modified example, the first beam splitter 113 transmits the reference light split by the second beam splitter 114 without reflecting it toward the second window 122. On the other hand, the first beam splitter 113 transmits part of the resonant light reflected back from the inside of the optical resonator 112, and reflects part of the resonant light to extract part of the laser light from the light source unit 110. As described above, the first beam splitter 113 is disposed to split the resonant light (i.e., the output light resonant with optical resonator 112) to be partially output to the frequency monitor 130.

In a case in which the first beam splitter 113 is disposed in this manner, not only the resonant light, but also non-resonant light can be monitored by the frequency monitor 130. In FIG. 9, the optical path indicated by a solid line is an optical path through which only the resonant light passes, among the light beams reflected by the first beam splitter 113. The optical paths indicated by dotted lines are optical paths through which the resonant light and the non-resonant light pass. The non-resonant light is indicated by a dotted line in FIG. 9. The non-resonant light is light that is regularly reflected without entering the optical resonator 112. The non-resonant light mentioned above, after passing through the first beam splitter 113, does not return to the semiconductor laser element 111 even when it is reflected by the second beam splitter 114. When resonance occurs, only the resonant light passes through the optical path indicated by the dotted line.

However, the non-resonant light reflected by the first beam splitter 113 passes through the second window 122 and is output toward the frequency monitor 130. As described above, the first beam splitter 113 is disposed to split the non-resonant light (i.e., the output light not resonant with optical resonator 112) to be partially output toward the frequency monitor 130. Thus, the frequency monitor 130 can monitor two beams of the resonant light and the non-resonant light.

In this case, when the emitted light does not resonate with the optical resonator 112, only one interference fringe obtained by the non-resonant light is observed in the frequency monitor 130. On the other hand, when the emitted light resonates with the optical resonator 112, two interference fringes obtained by the resonant light passing through the optical path indicated by the solid line and the resonant light passing through the optical path indicated by the dotted line are observed in the frequency monitor 130. As described above, one interference fringe is observed in the non-resonant state, and two interference fringes are observed in the resonant state. The resonant state and the non-resonant state can be distinguished from each other based on the number of interference fringes observed.

Accordingly, the control circuit 150 can determine whether the emitted light has resonated with the optical resonator 112 based on the output of the frequency monitor 130. Because of this, in the present modified example, the third window 123 and the photodiode 140 are unnecessary. Depending on the arrangement of the optical elements, the frequency monitor 130 can observe only the interference fringe of the resonant light without monitoring the interference fringe of the non-resonant light. In this case as well, the control circuit 150 can determine whether the emitted light has resonated with the optical resonator 112 based on the output of the frequency monitor 130, and therefore the photodiode 140 is unnecessary. This makes it possible to reduce the number of components.

### Second Modified Example of First Embodiment

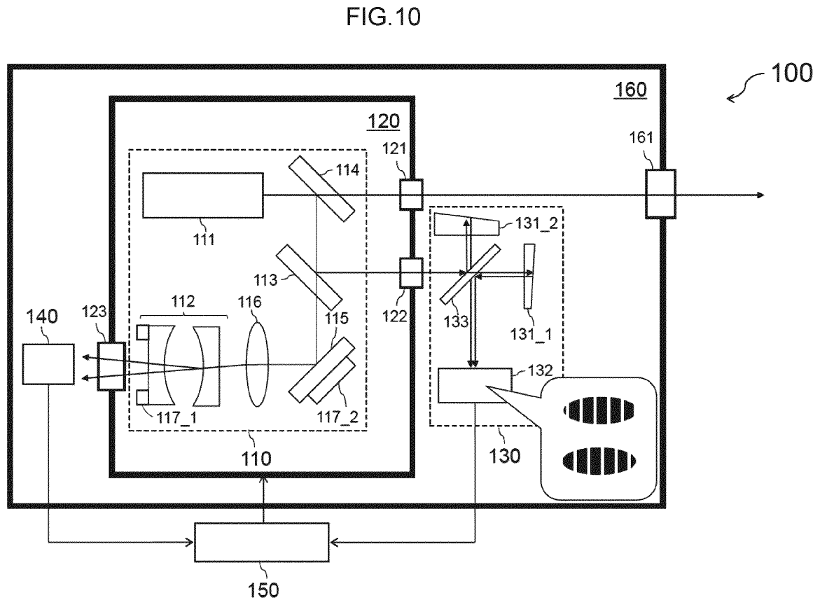

FIG. 10 is a diagram illustrating a configuration of the laser device 100 according to a second modified example of the first embodiment. The present modified example differs from the first embodiment in the following points.
The frequency monitor 130 further includes a third beam splitter 133.
The wedge 131 includes a first wedge 131_1 and a second wedge 131_2.

The third beam splitter 133 transmits part of the laser light extracted from the light source unit 110 and reflects part of the laser light. The transmitted light that passes through the third beam splitter 133 is incident on the first wedge 131_1. On the other hand, the light reflected by the third beam splitter 133 is incident on the second wedge 131_2.

In this case, two interference fringes caused by the first wedge 131_1 and the second wedge 131_2 are observed in the frequency monitor 130. In this case, a thickness L₁ of the first wedge 131_1 and a thickness L₂ of the second wedge 131_2 are different from each other. In this case, a free spectral range FSR_{w1} of the first wedge 131_1 and a free spectral range FSR_{w2} of the second wedge 131_2 have different values. This is because the FSR is inversely proportional to the thickness of the wedge. Therefore, a measurable frequency range for the frequency monitor 130 can be widened, and the measurement resolution can also be enhanced.

When FSR_{w1} and FSR_{w2} of the two wedges are different, the measurable frequency range can be widened, and the measurement resolution can also be enhanced. Accordingly, a wedge angle θ₁ of the first wedge 131_1 and a wedge angle θ₂ of the second wedge 131_2 may be different from each other. In addition, the wedge thicknesses may be different and the wedge angles may also be different so that the FSRs are different from each other.

A case in which the wedge 131 includes two wedges is described in FIG. 10 as an example, but the wedge 131 may include three or more wedges. This can allow the laser device 100 to meet various usage environments.

### Second Embodiment

FIG. 11A is a diagram illustrating a configuration of a laser device 100 according to a second embodiment. FIG. 11B is a diagram illustrating arrangement of the laser device 100 according to the second embodiment. The present embodiment differs from the first embodiment in the following points.
The laser device 100 further includes an optical isolator 210.
The laser device 100 further includes a first output mirror 220_1 and a second output mirror 220_2.
The laser device 100 further includes an optical amplifier 230.
The laser device 100 further includes a third Peltier element 183.

The optical isolator 210, the output mirror 220, and the optical amplifier 230 may be mounted on the second stage 172. These elements may be disposed in the order of the optical isolator 210, the first output mirror 220_1, the second output mirror 220_2, and the optical amplifier 230, as viewed from the first window 121 side, in an optical path of the output light. That is, in the present embodiment, the laser device 100 may further include the optical amplifier 230 disposed in the optical path of the output light, and the optical isolator 210 disposed in an optical path between the second beam splitter 114 and the optical amplifier 230.

The optical isolator 210 is an optical element through which light passes only in one direction. The optical isolator 210 may allow the output light to pass therethrough only in one direction from the first window 121 to the first output mirror 220_1. This can inhibit unnecessary light from entering the light source unit 110 from the outside.

The first output mirror 220_1 and the second output mirror 220_2 reflect the output light transmitted through the optical isolator 210 toward the optical amplifier 230 to adjust the optical axis.

The optical amplifier 230 amplifies the output light. As the optical amplifier 230, for example, an SOA may be used. In this case, an SOA of any type such as a resonant type, a traveling wave type, or a tapered type may be used. Examples of the semiconductor material of the SOA include III-V group semiconductors such as a gallium nitride (GaN) semiconductor, a gallium arsenide (GaAs) semiconductor, and an indium phosphide (InP) semiconductor.

The third Peltier element 183 configured to adjust the temperature of the optical amplifier 230 may be mounted near the optical amplifier 230 on the second stage 172. The control circuit 150 can adjust the temperature of the optical amplifier 230 by controlling a current supplied to the third Peltier element 183.

When a PCSEL element or an MOPA element is used as the semiconductor laser element 111, the semiconductor laser element 111 can oscillate with high power, and therefore the optical amplifier 230 may be omitted.

Further, instead of the optical isolator 210 and the optical amplifier 230, an optical integrated circuit in which the optical amplifier 230 and the optical isolator 210 are integrated on a chip may be disposed at a subsequent stage of the second output mirror 220_2. This can reduce the number of components, so that the laser device 100 can be reduced in size.

### Modified Example of Second Embodiment

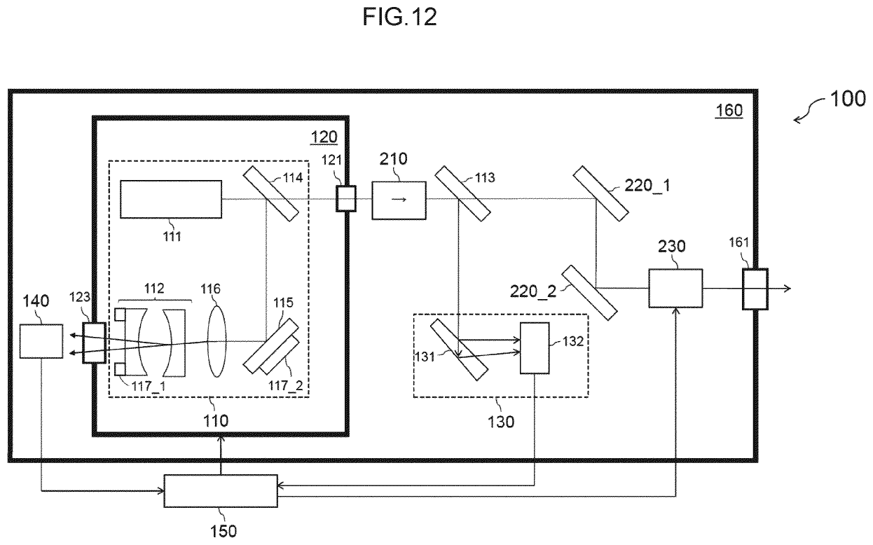

FIG. 12 is a diagram illustrating a configuration of the laser device 100 according to a modified example of the second embodiment. The present modified example differs from the second embodiment in the following points.
The first beam splitter 113 is disposed outside the light source unit 110.
The first cover 120 is not provided with the second window 122.

In the present modified example, the first beam splitter 113 is not disposed in the light source unit 110, but is disposed in the optical path of the output light, that is, in the optical path between the optical isolator 210 and the first output mirror 220_1 in this case. In this case, the first beam splitter 113 reflects part of the output light toward the frequency monitor 130. Therefore, it is unnecessary to extract laser light from the light source unit 110 separately from the output light. Thus, it is also unnecessary for the first cover 120 to be provided with the second window 122. This makes it possible to reduce the size of the light source unit 110 and to enhance the airtightness of the space in which the light source unit 110 is mounted.

When part of the output light is extracted, the output is reduced. Further, in a case in which an extra optical element is placed in the optical path of the output light, this may cause degradation in beam quality. Because of this, the first beam splitter 113 is preferably disposed inside the light source unit 110. However, there may be a case in which the first beam splitter 113 needs to be disposed outside the light source unit 110 due to a space limitation or the like. According to the present modified example, even in such a case, the output light can be amplified by the optical amplifier 230, and thus the reduction in the output can be compensated for.

### Third Embodiment

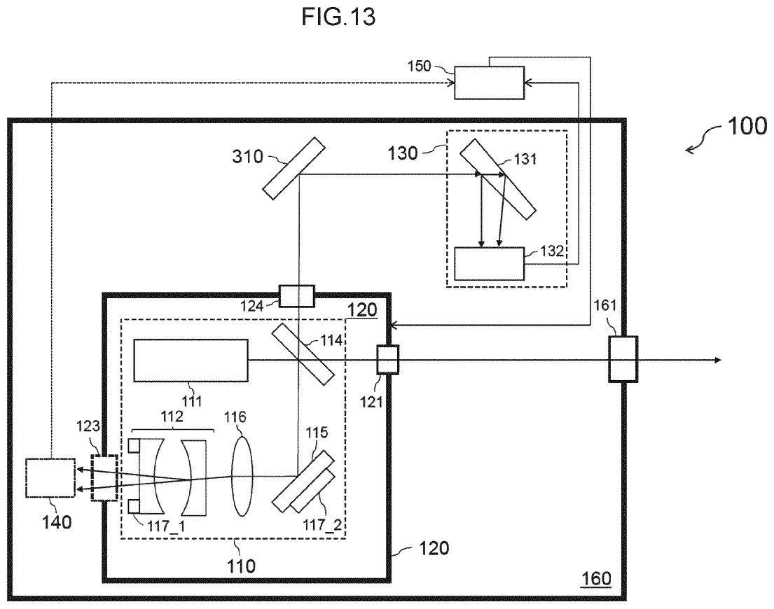

FIG. 13 is a diagram illustrating a configuration of a laser device 100 according to a third embodiment. The present embodiment differs from the first embodiment in the following points.
The light source unit 110 does not include the first beam splitter 113.
The first cover 120 is provided with a fourth window 124 in place of the second window 122.
The laser device 100 further includes a monitoring mirror 310.

As described above, the resonant light reflected back from the inside of the optical resonator 112 is collimated again by the lens 116, and then reflected by the mirror 115 toward the second beam splitter 114. Here, part of the resonant light incident on the second beam splitter 114 is reflected and returns to the semiconductor laser element 111. At this time, part of the resonant light is transmitted through the second beam splitter 114. In the present embodiment, the transmitted light that is the resonant light having passed through the second beam splitter 114 in this manner is used for monitoring the frequency.

The fourth window 124 is a window for outputting the transmitted light that is the resonant light having passed through the second beam splitter 114 to the outside of the first cover 120. The monitoring mirror 310 reflects the transmitted light output from the fourth window toward the frequency monitor 130. In this case, the frequency monitor 130 monitors the frequency of the transmitted light that is the resonant light produced after the emitted light has resonated with the optical resonator 112 and passed through the second beam splitter 114.

According to the present embodiment, light that is originally wasted can be used for monitoring the frequency, and the size of the light source unit 110 can be reduced. On the other hand, the size of the entire laser device 100 may be increased by providing the monitoring mirror 310 separated from the light source unit 110.

In the present embodiment, as in the first modified example of the first embodiment, the frequency monitor 130 can monitor two beams of resonant light and non-resonant light. Therefore, it is unnecessary for the first cover 120 to be provided with the third window 123. The laser device 100 need not include the photodiode 140. Accordingly, whether or not to employ the present embodiment may be determined by comprehensively considering the above-discussed points.

### Fourth Embodiment

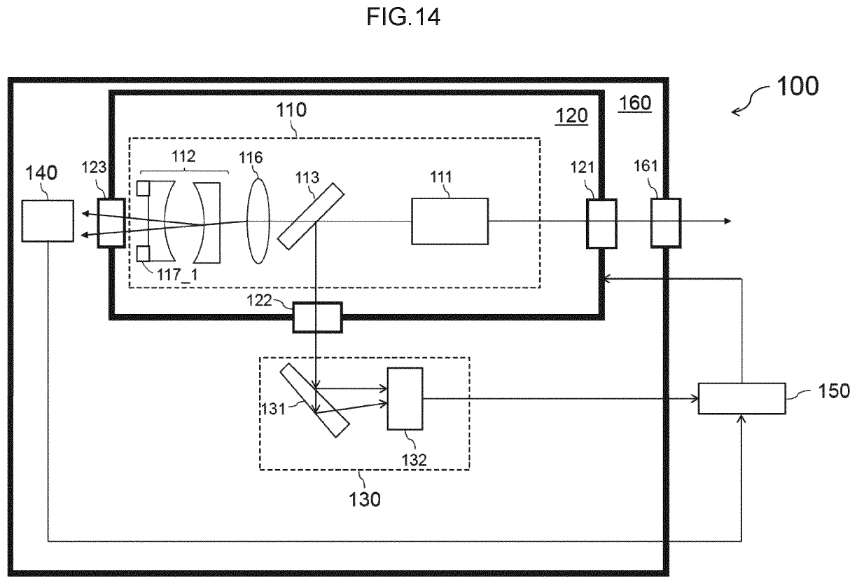

FIG. 14 is a diagram illustrating a configuration of a laser device 100 according to a fourth embodiment. The present embodiment differs from the first embodiment in the following points.
The semiconductor laser element 111 is an element that can emit light from both surfaces thereof.
The light source unit 110 does not include the second beam splitter 114.
The light source unit 110 does not include the mirror 115.

In the present embodiment, the semiconductor laser element 111 is a distributed feedback laser element (DFB laser element) or a distributed Bragg reflector laser element (DBR laser element), which can emit light from a first surface and a second surface on a side opposite the first surface. The light source unit 110 outputs light emitted from the first surface as output light. In this case of the present embodiment, light emitted from the second surface is used as reference light. The light emitted from the second surface is also used for monitoring the frequency.

Therefore, the second beam splitter 114 is unnecessary because the emitted light does not need to be split into the output light and the reference light. When the semiconductor laser element 111 and the optical resonator 112 are disposed on a straight line, the mirror 115 may be omitted. In this case, the first beam splitter 113 may be disposed in an optical path between the second surface of the semiconductor laser element 111 and the optical resonator 112, and may transmit part of the light emitted from the second surface and introduce the transmitted light into the optical resonator 112 as reference light. Further, the first beam splitter 113 may reflect part of the light emitted from the second surface toward the frequency monitor 130.

According to the present embodiment, the self-injection locking can be performed using the light leaking to the rear side of the semiconductor laser element 111, and this light can also be used for monitoring the frequency.

### Modified Example of Fourth Embodiment

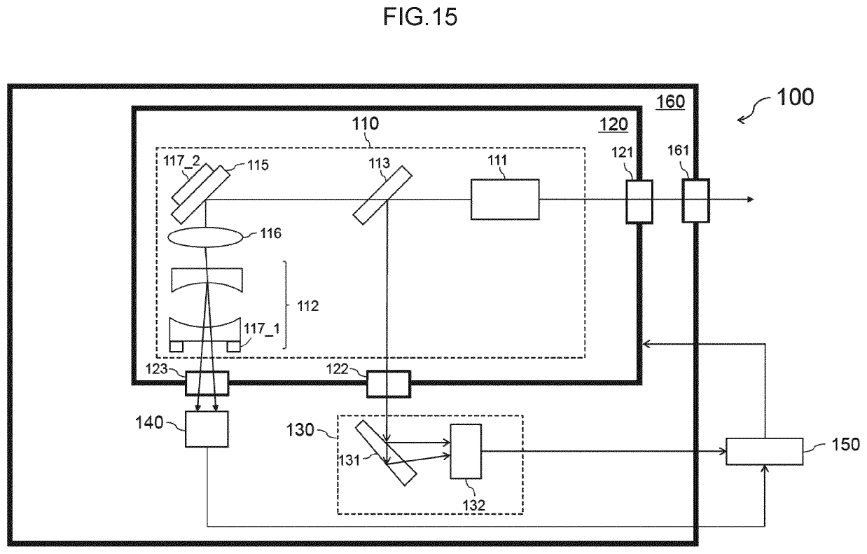

FIG. 15 is a diagram illustrating a configuration of the laser device 100 according to a modified example of the fourth embodiment. The present modified example differs from the fourth embodiment in the following points.
The light source unit 110 includes a mirror 115.

In the present modified example, the mirror 115 reflects the reference light having passed through the first beam splitter 113 toward the optical resonator 112.

According to the present modified example, the feedback path length LEB can be changed, and thus the narrow linewidth state can be easily maintained or easily adjusted.

### Fifth Embodiment

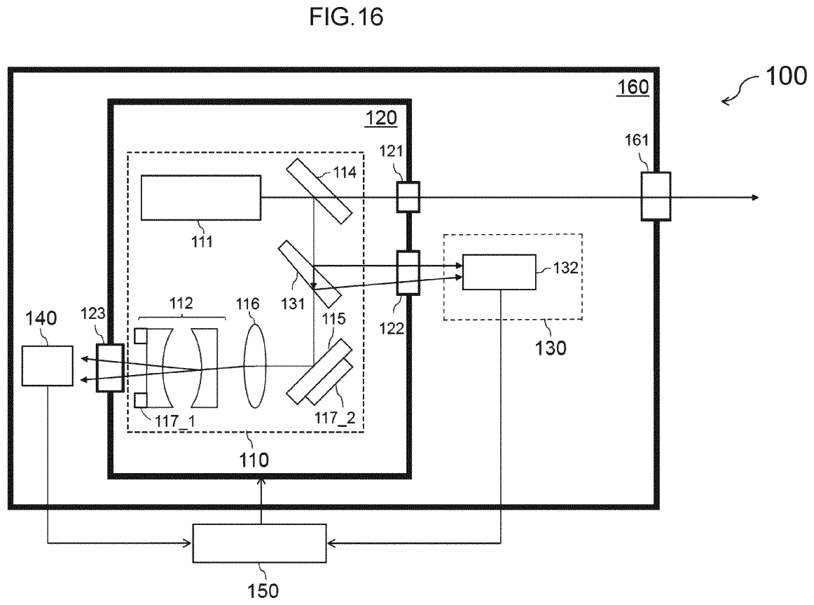

FIG. 16 is a diagram illustrating a configuration of a laser device 100 according to a fifth embodiment. The present embodiment differs from the first embodiment in the following points.
The light source unit 110 does not include the first beam splitter 113.
The wedge 131 is provided in the light source unit 110, not in the frequency monitor 130.

In the present embodiment, the wedge 131 also serves as the first beam splitter 113. The wedge 131 is disposed in an optical path between the semiconductor laser element 111 and the optical resonator 112, specifically, between the second beam splitter 114 and the mirror 115 in this case.

According to the present embodiment, because the functions of the first beam splitter 113 and the wedge 131 are combined into one element, the first beam splitter 113 is unnecessary, so that the number of optical elements can be reduced by one.

In the present embodiment, the wedge 131 is significantly affected by the temperature adjustment by the first Peltier element 181. Due to this, when the control circuit 150 controls a current supplied to the first Peltier element 181 to control the frequency of the laser light, the thickness of the wedge 131 may also be changed. Therefore, the present embodiment may be effective only in a case in which the control circuit 150 controls a current supplied to the semiconductor laser element 111 or a voltage of the piezoelectric element 117 to control the frequency of the laser light.

Although the plural embodiments of the present disclosure have been cited and described above, these embodiments are merely examples, and various modifications can be made without departing from the scope of the present disclosure. It is needless to say that the scope of the present disclosure is not limited to these embodiments. In particular, all forms in which the embodiments can be combined within a range in which no technical contradiction occurs may also be included in the scope of the present disclosure. For example, the optical isolator 210, the first output mirror 220_1, the second output mirror 220_2, and the optical amplifier 230 may be applied to an embodiment in which these are not illustrated.

An occurrence rate of oscillation frequencies being locked to a predetermined resonant frequency was examined using a frequency monitor in an example in which the frequency of output light was controlled and in a comparative example in which the frequency of output light was not controlled.

### Example 1

As a laser device of Example 1, a laser device including a self-injection locked type light source unit, a frequency monitor, and a control circuit was prepared. The frequency monitor was formed of a wedge and a light-receiving element for receiving light reflected on both surfaces of the wedge. The laser device of Example 1 has a configuration in which the first output mirror 220_1, the second output mirror 220_2, and the optical amplifier 230 are removed from the laser device 100 illustrated in FIG. 12. The narrowed spectral linewidth of the output light was 1 MHz or less. The FSR of the optical resonator was 7 GHZ, and the measurable range for the frequency monitor was ±11 GHz (that is, 22 GHZ). Therefore, the frequency monitor was able to detect the resonant frequencies adjacent to the predetermined frequency. In Example 1, steps S151 to S155 in the control flow to be performed by the control circuit illustrated in FIG. 6 were performed.

### Comparative Example 1

A laser device of Comparative Example 1 is different from the laser device of Example 1 in the control flow to be performed by the control circuit in the following points. That is, in the laser device of Comparative Example 1, steps S151 to S154 in the control flow to be performed by the control circuit were performed, and step S155 was not performed.

### Measurement

The laser device was driven, and the occurrence rate of oscillation frequencies was measured. As described above, the laser device of Example 1 measured the occurrence rate of oscillation frequencies after the control circuit performed all of the flow from step S151 to step S155. In Example 1, the oscillation frequency of laser light emitted from the semiconductor laser element was controlled by controlling the value of a current supplied to the semiconductor laser element in step S155. The laser device of Comparative Example 1 measured the occurrence rate of oscillation frequencies after the control circuit performed step S151 to step S154.

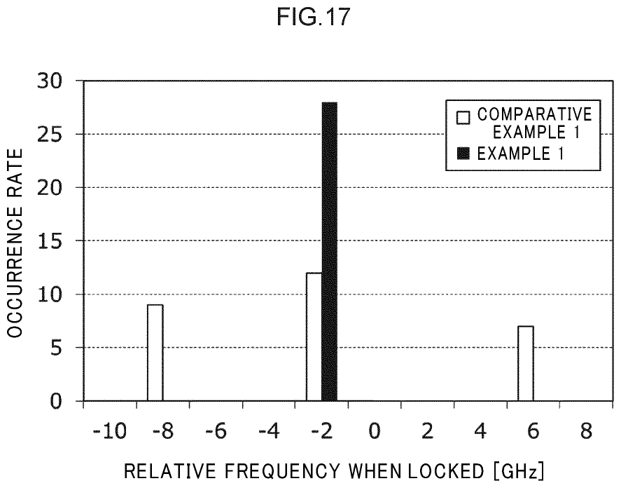

FIG. 17 is a histogram illustrating occurrence rates of oscillation frequencies in Example 1 and Comparative Example 1. The horizontal axis of the histogram represents a deviation amount between the resonant frequency of the optical resonator and the zero point of the frequency monitor (that is, a relative frequency), while the vertical axis of the histogram represents the occurrence rate. As illustrated in FIG. 17, in Example 1, all the oscillation frequencies were locked at a predetermined frequency and the laser light oscillated. This resonant frequency is a target resonant frequency selected from the resonant frequencies of the optical resonator. All the laser light, including that in several hundred tests not illustrated in the histogram, oscillated at the target resonant frequency. On the other hand, in Comparative Example 1, the laser light oscillated not only at the target resonant frequency, but also at other resonant frequencies deviated by ±1 FSR. The following factors are conceivable as the reason why bars in the histogram of Comparative Example 1 are not depicted at equal intervals: the scale of the horizontal axis being represented by integers to make the result more easily understood; measurement accuracy of the frequency monitor; and different widths of frequencies at which resonance can occur for each of the resonant frequencies. However, these factors do not affect the results of this measurement. From the above measurement, it has been found that the laser light can oscillate stably at the target resonant frequency by performing the control by the control circuit based on the output of the frequency monitor.

### REFERENCE CHARACTER LIST

100 Laser device
110 Light source unit
111 Semiconductor laser element
112 Optical resonator
113 First beam splitter
114 Second beam splitter
115 Mirror
116 Lens
117_1 First piezoelectric element
117_2 Second piezoelectric element
120 First cover
121 First window
122 Second window
123 Third window
124 Fourth window
130 Frequency monitor
131 Wedge
131_1 First wedge
131_2 Second wedge
132 Light-receiving element
133 Third beam splitter
140 Photodiode
150 Control circuit
160 Second cover
161 Output window
171 First stage
172 Second stage
181 First Peltier element
182 Second Peltier element
183 Third Peltier element
210 Optical isolator
220_1 First output mirror
220_2 Second output mirror
230 Optical amplifier
310 Monitoring mirror

What is claimed is:

1. A laser device comprising:
a light source unit that is a self-injection locked type and comprises a semiconductor laser element and an optical resonator;
a frequency monitor configured to monitor a frequency of light extracted from the light source unit by using an interferometer; and
a control circuit configured to control at least one of an oscillation frequency of light emitted from the semiconductor laser element and resonant frequencies of the optical resonator, based on an output of the frequency monitor, wherein:
a free spectral range of the interferometer is different from a free spectral range of the optical resonator, and
an interference signal from the frequency monitor is different at each of adjacent two of the resonant frequencies of the optical resonator.

2. The laser device according to claim 1, wherein:
the light source unit further comprises a first beam splitter disposed in an optical path between the semiconductor laser element and the optical resonator, and
the frequency monitor is configured to monitor the frequency of the laser light split by the first beam splitter.

3. The laser device according to claim 2, wherein:
at least part of the light emitted from the semiconductor laser element resonates in the resonator, and
the first beam splitter splits the resonant light to be partially output to the frequency monitor.

4. The laser device according to claim 3, wherein:
at least part of the light emitted from the semiconductor laser element does not resonate in the resonator, and
the first beam splitter splits the non-resonant light to be partially output to the frequency monitor.

5. The laser device according to claim 2, wherein:
the semiconductor laser element is a distributed feedback laser element or distributed Bragg reflector laser element configured to emit light from a first surface and a second surface on a side opposite the first surface,
the light source unit configured to output light emitted from the first surface as output light, and
the first beam splitter is disposed in an optical path between the second surface of the semiconductor laser element and the optical resonator, and introduces part of light emitted from the second surface into the optical resonator as reference light.

6. The laser device according to claim 1, wherein the light source unit further comprises a second beam splitter configured to split the light that is emitted from the semiconductor laser element into output light to be output from the light source unit and reference light to be introduced into the optical resonator.

7. The laser device according to claim 6, further comprising:
an optical amplifier disposed in an optical path of the output light from the light source.

8. The laser device according to claim 2, wherein:
the light source unit further comprises a second beam splitter configured to split the light that is emitted from the semiconductor laser element into output light to be output from the light source unit and reference light to be introduced into the optical resonator, and
the laser device further comprises:
an optical amplifier disposed in an optical path of the output light from the light source, and
an optical isolator disposed in an optical path between the second beam splitter and the optical amplifier.

9. The laser device according to claim 6, wherein:
at least part of the light emitted from the semiconductor laser element resonates in the resonator, and
the frequency monitor is configured to monitor a frequency of transmitted light having passed through the second beam splitter.

10. The laser device according to claim 1, wherein the frequency monitor comprises a wedge and a light-receiving element configured to receive light reflected on first and second surfaces of the wedge.

11. The laser device according to claim 1, wherein:
the frequency monitor comprises:
a third beam splitter,
a first wedge on which transmitted light passing through the third beam splitter is incident,
a second wedge on which reflected light reflected by the third beam splitter is incident, and
a light-receiving element configured to receive light reflected on a surface of the first wedge and a surface of the second wedge, and
a thickness of the first wedge and a thickness of the second wedge are different from each other.

12. The laser device according to claim 1, wherein:
the light source unit further comprises a wedge disposed in an optical path between the semiconductor laser element and the optical resonator, and
the frequency monitor comprises a light-receiving element configured to receive light reflected on first and second surfaces of the wedge.

13. The laser device according to claim 1, wherein:
the light source unit further comprises a mirror to which a piezoelectric element is attached, the mirror being disposed in an optical path between the semiconductor laser element and the optical resonator.

14. The laser device according to claim 1, further comprising:
a first stage on which the light source unit is mounted;
a second stage on which the first stage is mounted;
a first Peltier element disposed between the first stage and the second stage; and
a first cover covering the first stage, wherein:
a space surrounded by the first stage and the first cover is hermetically sealed.

15. The laser device according to claim 14, further comprising:
a second Peltier element configured to adjust a temperature of the frequency monitor, wherein:
the frequency monitor and the second Peltier element are mounted on the second stage.
